(19) United States
(12) Patent Application Publication
(10) Pub. No.: US 2026/0206582 A1
(43) Pub. Date: Jul. 16, 2026

(54) APPARATUS WITH THERMAL DISTRIBUTION NETWORK AND METHODS FOR OPERATING THE SAME

(71) Applicant: Micron Technology, Inc., Boise, ID (US)

(72) Inventors: Lingming Yang, Meridian, ID (US); Raghukiran Sreeramaneni, Frisco, TX (US); Nevil N. Gajera, Meridian, ID (US); Guy S. Perry, IV, Plano, TX (US)

(21) Appl. No.: 19/406,941

(22) Filed: Dec. 3, 2025

Related U.S. Application Data
(60) Provisional application No. 63/744,732, filed on Jan. 13, 2025.

(51) Int. Cl. H10W 40/20; H10B 80/00; H10D 80/30; H10P 58/00; H10W 20/00; H10W 20/20; H10W 20/42; H10W 20/43; H10W 40/00; H10W 40/25; H10W 90/00; H10W 90/20; H10W 90/26; H10W 70/60; H10W 90/10

(52) U.S. Cl. CPC H10W 40/233; H10B 80/00; H10D 80/30; H10P 58/00; H10W 20/0261; H10W 20/2134; H10W 20/42; H10W 20/432; H10W 40/03; H10W 40/258; H10W 90/26; H10W 90/288; H10W 90/297; H10W 90/722; H10W 70/611; H10W 90/10; H10W 90/401; H10W 90/724; H10W 90/7295

(57) ABSTRACT

Methods, apparatuses, and systems related to a thermal distribution network are described. The thermal distribution network includes thermally conductive material configured to route thermal energy, generated by a supporting device, along a vertical path and through one or more portions of a semiconductor device stacked over the supporting device.

### CROSS-REFERENCE TO RELATED APPLICATION(S)

The present application claims priority to U.S. Provisional Patent Application No. 63/744,732, filed January 13, 2025, the disclosure of which is incorporated herein by reference in its entirety.

### TECHNICAL FIELD

The disclosed embodiments relate to devices, and, in particular, to semiconductor devices with a chiplet-based thermal distribution network and methods for operating the same.

### BACKGROUND

An apparatus (e.g., a processor, a memory system, and/or other electronic apparatus) can include one or more semiconductor circuits configured to store and/or process information. For example, the apparatus can include a memory device, such as a volatile memory device, a non-volatile memory device, or a combination device. Memory devices, such as dynamic random-access memory (DRAM) and High Bandwidth Memory (HBM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing operating speeds or otherwise reducing operational latency, increasing reliability, increasing data retention, increasing functionalities, reducing power consumption, or reducing manufacturing costs, among other metrics.

### BRIEF DESCRIPTION OF THE DRAWINGS

FIG. 1A is a cross-sectional view of an example system-in-package (SiP) device.

FIG. 1B is a cross-sectional view of an example chiplet.

FIG. 1C is a cross-sectional view of an example die in the chiplet.

FIG. 1D is a plan view of the die.

FIG. 2A is a cross-sectional view of a SiP device having a thermal distribution network in accordance with an embodiment of the present technology.

FIG. 2B is a cross-sectional view of a portion of a chiplet having the thermal distribution network in accordance with an embodiment of the present technology.

FIG. 2C is a plan view of the chiplet in accordance with an embodiment of the present technology.

FIG. 3 is a cross-sectional view of a memory die in accordance with an embodiment of the present technology.

FIG. 4 is a flow diagram illustrating an example method of manufacturing an apparatus in accordance with an embodiment of the present technology.

FIG. 5 is a schematic view of a system that includes an apparatus in accordance with an embodiment of the present technology.

### DETAILED DESCRIPTION

As described in greater detail below, the technology disclosed herein relates to an apparatus, such as for memory systems, systems with memory devices, related methods, etc., having a thermal management network. In some embodiments, the thermal management network can be configured to conduct and route, such as by redirecting distribution along vertical and/or horizontal directions, thermal energy or heat within a heterogeneous integrated chiplet. The heterogenous integrated chiplet can have multiple semiconductor dies integrated (e.g., via wafer bonding or other similar techniques) into a single chip to improve performance, power, area, cost, time to market, etc. One example of the heterogeneous integrated chiplet can include a memory device, such as a HBM device that includes multiple memory dies (e.g., DRAM dies) stacked on an interface die.

The thermal management network can include structures, such as vias, metal layers (e.g., traces), pads, and/or the like, configured to conduct and route the thermal energy within the chiplet. In some embodiments, functional circuitry within the chiplet can be rearranged to accommodate and enhance the thermal routing. Accordingly, the thermal management network can allow heat from a

lower device to travel through and across thicknesses of multiple stacked dies, across lateral directions on the multiple stacked dies, or both, thereby preventing overheating of one or a set of lower-positioned dies and increasing the overall thermal dissipation rate/capacity for the chiplet. Moreover, the thermal management network can route the thermal energy into semiconductor substrates, such as through thermal pads on the substrates and vertical vias connected thereto.

For illustrative purposes, the thermal management network is described within the context of the HBM. However, it is understood that the thermal management network can be implemented in other types of semiconductor devices or chiplets.

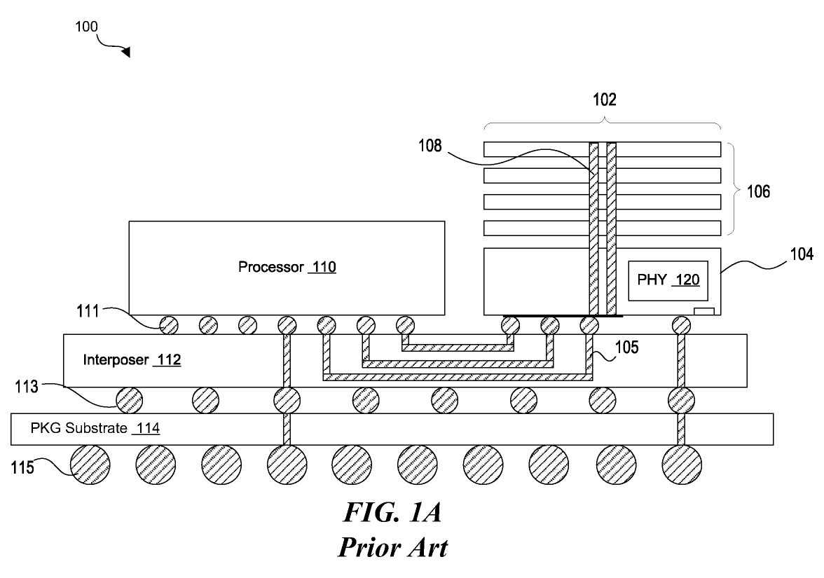

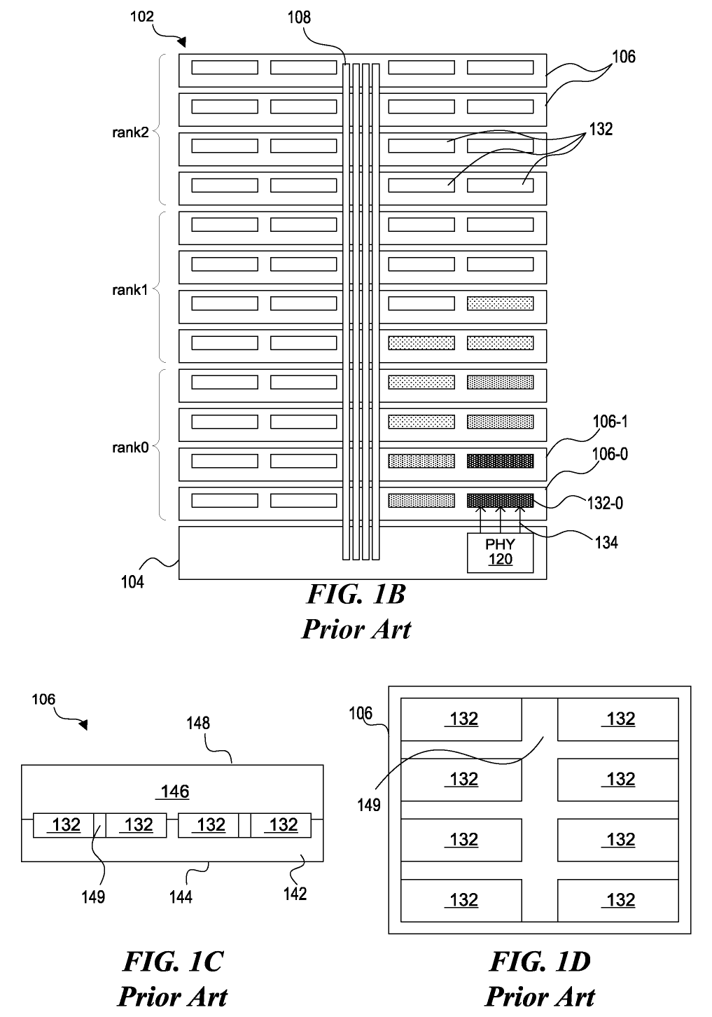

To illustrate the improvements provided by the thermal management network, FIGS. 1A – 1D illustrate various aspects of a conventional chiplet (i.e., without the thermal management network). FIG. 1A is a cross-sectional view of an example system-in-package (SiP) device 100, FIG. 1B is a cross-sectional view of an example chiplet (e.g., a memory device 102), FIG. 1C is a cross-sectional view of an example die (e.g., a core memory die 106) in the chiplet, and FIG. 1D is a plan view of the die 106.

Referring now to FIG. 1A, The SiP 100 can include the memory device 102 along with a processor 110 (e.g., a central processing unit (CPU), a graphics processing unit (GPU), or the like), which are packaged together on a package substrate 114 along with an interposer 112. The processor 110 may act as a host device of the SiP 100.

In some embodiments, the memory device 102 may be a HBM device that includes an interface die (or logic die) 104 and the one or more memory core dies 106 stacked on the interface die 104. The memory core dies 106 can include DRAM devices/dies, NAND devices/dies, and/or other types of memory devices (e.g., static RAM (SRAM)) as main memory configured to store data provided by the processor 110 and to provide access of the stored data to the processor 110. The memory device 102 can further include additional and/or supplementary memory circuits (e.g., SRAM, DRAM, NAND, etc.), located within and/or outside of the core dies 106, configured for internal uses (e.g., remaining inaccessible to the processor 110). The memory device 102 can include one or more through silicon vias (TSVs) 108, which may be used to couple the interface die 104 and the core dies 106.

The interposer 112 (e.g., a silicon interposer) can provide electrical connections between the processor 110, the memory device 102, and/or the package substrate 114. For example, the processor 110 and the memory device 102 may both be coupled to the interposer 112 by a number of internal connectors (e.g., micro-bumps 111). The interposer 112 may include channels 105 (e.g., an interfacing or a connecting circuit) that electrically couple the processor 110 and the memory device 102 through the corresponding micro-bumps 111. While three channels 105 are shown in FIG. 1, greater or fewer numbers of channels 105 may be used. The interposer 112 may be coupled to the package substrate by one or more additional connections (e.g., intermediate bumps 113, such as C4 bumps).

The package substrate 114 can provide an external interface for the SiP 100. The package substrate 114 can include external bumps 115, some of which may be coupled to the processor 110, the memory device 102, or both. The package substrate may further include direct access (DA) bumps coupled through the package substrate 114 and the interposer 112 to the interface die 104.

To communicating with external circuits, the memory device 102 can include a physical layer (PHY) circuit 120, such as a set of drivers, receivers, buffers, clocks, and/or the like. For example, the PHY 120 can generate and send the electrical signals corresponding to data (e.g., read data) to the processor 110. Similarly, the PHY 120 can receive signals (e.g., write data, commands, etc.) provided by the processor 110. Given the interfacing function, the PHY 120 can be included in the interfacing die 104, which may be located on the bottom of the memory device 102 to directly attach to the interposer 112 and the channels 105. During operation the PHY 120 can generate more heat than other circuits (e.g., charge storage circuits, read circuits, such as sense amps, write circuits, etc.) within the memory device 102. However, given the arrangement of the dies, the thermal energy from the PHY 120 can be effectively blocked at or about the interfacing die 104 and/or left without an effective conductive path.

To illustrate the heat transfer, or the lack thereof, FIG. 1B shows a cross-sectional view of the memory device 102. The illustrated memory device 102 can have 12 memory dies, organized into three ranks (e.g., rank0 – rank2, with each rank having four dies), stacked over the interfacing die 104. Each of the dies within the chiplet can include functional circuitry. For example, each of the core memory dies 106 can include a set of storage circuits (e.g., memory cells) arranged into arrays 132 or subarrays. The TSVs 108 can communicatively couple the memory dies and the arrays 132 to each other and/or the interfacing die 104.

During operation, a heat-generating circuit (e.g., the PHY 120) can generate and radiate thermal energy 134, which can be stored in nearby structures/circuits. As illustrated using different fills, the thermal energy 134 generated by the PHY 120 can be stored in a first die 106-0 directly attached to the interfacing die 104. Within the first die 106-0, a first array 132-0 overlapping the PHY 120 can be most affected by the thermal energy 134. Other surrounding circuits can also be affected by the thermal energy 134, with structures closer to the PHY 120 receiving more thermal energy than more distance structures. The intensity or the darkness in the fills represent the amount of thermal energy received from the PHY 120.

In some embodiments, the PHY 120 is located on a peripheral portion and/or a corner of the interfacing die 104. Moreover, as shown in FIG. 1C and 1D, the memory dies 106 have the arrays 132 arranged in a symmetrical pattern. Some of the arrays 132 occupy the peripheral portions of the memory dies 106. Thus, when mounted or attached over the interfacing die 104, the arrays 132 in the peripheral portions may overlap the PHY 120 and receive larger amounts of the thermal energy 134 than other arrays 132 in the same die.

Additionally, the memory dies 106 can include other features that prohibit thermal management of the memory device 102 of FIG. 1B. For example, each of the memory dies 106 can have the functional circuitry (e.g., the arrays 132) formed on a front side 142 of a corresponding semiconductor die. The memory dies 106 can each have a front end of the line (FEOL) structure over and/or further defining the front side 142. The FEOL can include the semiconductor substrate or the front side 142 thereof, the functional circuitry, or a combination thereof.

The memory dies 106 can each have a back end of the line (BEOL) 144 structure over the FEOL. The BEOL 144 can include metals (e.g., conductive planes, traces, and/or the like) and conductive vias that provide electrical connections to/from/between the functional circuitry. In facilitating the metals, such as to prevent unintended shorts, the BEOL 144 can include oxides, electrical insulators, and the like separating different conductive paths. The insulative separators can be disposed between the traces and/or form one or more layers disposed between and separating signaling planes (e.g., metal layers).

Often, the electrical insulator in the BEOL 144 are also thermal insulators. Accordingly, while the BEOL 144 may block some of the heat from reaching the arrays 132 and a corresponding semiconductor substrate 146, the BEOL 144 also traps the thermal energy below the frontside 144 and/or within the corresponding die 106. For example, the BEOL 144 of the first die 106-0 can prevent or reduce the thermal energy from dissipating out of the PHY 120, and the BEOL 144 of a second die 106-1 can prevent the thermal energy that made it into the first die 106-0 from dissipating through a backside 148 of thereof.

Similarly, the memory dies 106 can include periphery portions 149 between the arrays 132. The periphery portions 149 can also include electrical insulators to further isolate one array from another. However, as described above, the periphery portions 149 can become thermal insulators that prevent or reduce the dissipation of the thermal energy out of the corresponding die and/or a structure underneath the corresponding die.

### Example Thermal Distribution Networks

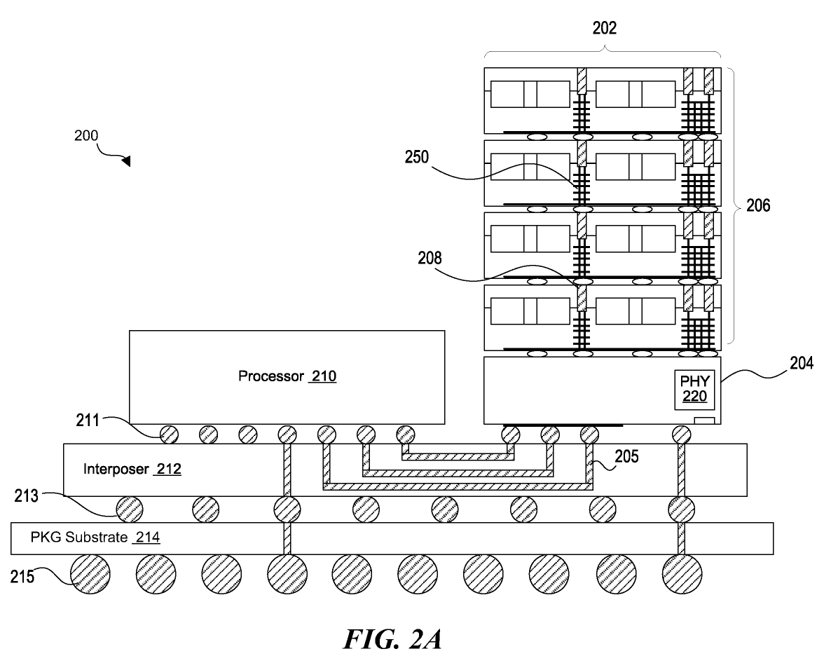

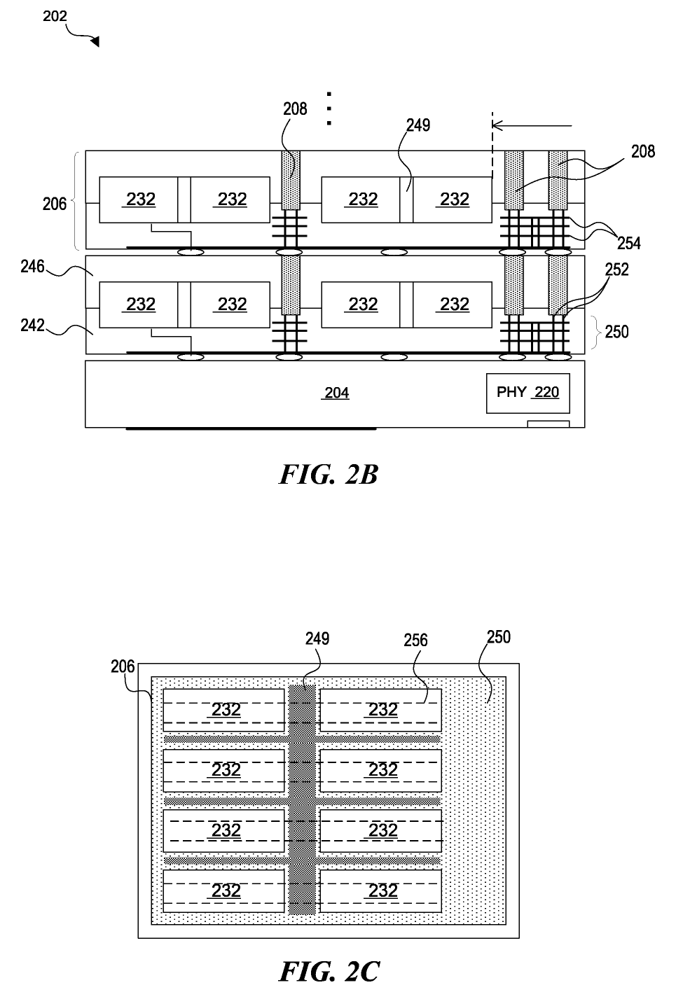

In contrast to the conventional computing devices, embodiments of the present technology can include the thermal distribution network for routing the thermal energy, such as within a chiplet, to more evenly distribute the thermal energy or heat and increase the dissipation rate of the thermal energy for the overall device. To illustrate this, FIG. 2A is a cross-sectional view of a SiP device 200 having a thermal distribution network 250 in accordance with an embodiment of the present technology.

In general, the SiP 200 can be similar to the SiP 100 of FIG. 1A. For example, the SiP 200 can include a processor 210 mounted on an interposer 212, which is further mounted on a package substrate 214. The interposer 212 can have channels 205 for routing signals between mounted devices. The processor 210 can be connected to the interposer 212 (e.g., the channels 205) through micro-bumps 211, and the interposer 212 can be connected to the package substrate 214 through intermediate bumps 213 (e.g., C4 bumps). The package substrate 214 can provide an external interface for the SiP 200, such as through external bumps 215.

Different from the SiP 100, the SiP 200 can have a chiplet, such as a memory device 202, having the thermal management network 250. The memory device 202 can include a heterogeneous integrated chiplet having one or more memory core dies 206 mounted on (e.g., bonded to) an interfacing die 204. The memory device 202 can have TSVs 208 extending vertically through each of the memory dies 206 to vertically route signals, such as across one or more dies and in/out of a die targeted for an operation.

The chiplet can have one or more targeted heat-generating circuits. For example, the memory device 202 can have a PHY 220 that generates more heat than other circuits. The PHY 220 can be located in the interfacing die 204. In some embodiments, the PHY 220 can be located at a peripheral or a corner portion of the interfacing die 204.

The thermal distribution network 250 can be configured to conduct and route, such as by redirecting distribution along vertical and/or horizontal directions, thermal energy or heat within the chiplet. The thermal management network 250 can include structures, such as vias, metal layers (e.g., traces), pads, and/or the like, configured to conduct and route the thermal energy within the chiplet. In other words, the thermal distribution network 250 can include a portion of (e.g., the thermally conductive components within) BEOL 242 configured to receive or draw thermal energy away from a supporting structure below. Moreover, the chiplet can include the functional circuitry reconfigured or rearranged to accommodate and enhance the thermal routing.

To further illustrate the thermal routing, FIG. 2B is a cross-sectional view of a portion of a chiplet (the memory device 202) having the thermal distribution network 250, and FIG. 2C is a plan view of the chiplet, both in accordance with an embodiment of the present technology. Referring to FIGS. 2B and 2C, together, the chiplet can include a target heat generating circuit along with other functional circuits that may be adversely affected by the generated heat. For example, the memory dies 206 can include arrays 232 that are adversely affected by the thermal energy from the PHY 220. The thermal distribution network 250 can route the thermal energy away from the heat-generating circuit, around other circuits (e.g., the arrays 232), across lateral directions (e.g., across one or more dies), and/or across vertical directions (e.g., across a thickness of one or more dies).

As an illustrative example, the thermal distribution network 250 can include internal vias 252, lateral thermal connections 254, or a combination thereof. The internal vias 252 can extend vertically through the BEOL 242 (e.g., the thermally insulative oxide layers therein) formed on a frontside of a semiconductor substrate 246. The internal vias 252 can directly contact or be integral with the TSVs 208, the lateral thermal connections 254, or both. The lateral thermal connections 254 can include thermally conductive structures, such as traces, that extend laterally within or across the BEOL 242. In some embodiments, the lateral thermal connections 254 can include metal layers or portions thereof that extend within a targeted thermal route/region and independent of electrical connections. For example, the lateral thermal connections 254 can extend/overlap with the TSVs and/or the heat-generating structure or area without being included in a point-to-point electrical path. The lateral thermal connections 254 and the internal vias 252 can include thermally conductive material, such as gold, copper, graphene, or the like.

The thermal distribution network 250 can be configured to increase a density of thermally conductive material over a targeted heat-generating circuit, such as the PHY 220. In some embodiments, the lateral thermal connections 254 can include traces having minimum spacing (e.g., finest pitch according to manufacturing requirements) and/or greater trace widths at targeted locations, such as portions overlapping the heat generating areas (e.g., the PHY 220). The lateral thermal connections 254 can further include traces on all available layers. Accordingly, in comparison to other signal/voltage connecting traces that occupy locations according to signaling needs, the lateral thermal connections 254 for the thermal distribution network 250 can increase the density of thermally conductive material within the insulative material of the BEOL at the targeted locations. Similarly, the internal vias 252 can have the minimum separation distance (e.g., finest pitch) available according to the manufacturing requirements.

Through the increased density (e.g., 20% or more metallic material within the targeted portions) of thermally conductive material, the thermal distribution network 250 can provide an upward path for the thermal energy through the BEOL 242 and the corresponding dies using the internal vias 252, the lateral thermal connections 254, and the TSVs 208. Additionally, the thermal distribution network 250 can spread or dissipate the thermal energy laterally, such as using the lateral thermal connections 254. The lateral thermal connections 254 can further route the thermal energy to the internal vias 252 and TSVs 208 that are laterally displaced from (e.g., not overlapping) the heat-generating circuit.

In some embodiments, the thermal distribution network 250 can be used to provide electrical connections, such as electrical ground or power. For example, the thermal distribution network 250 can function as and/or be connected to a power network 256. In other embodiments, the thermal distribution network 250 can be isolated from electrical connections. The isolated thermal distribution network 250 can remain floating or be grounded through a separate or dedicated connection.

To accommodate the thermal distribution network 250, the functional circuitry in the overlapping dies can be offset or rearranged. For example, the arrays 232 can be offset from the peripheral portion overlapping the heat generating circuit. Instead, the thermal distribution network 250 and the TSVs 208 can be formed within the peripheral portion to allow the thermal energy to travel upward. In some embodiments, the thermal distribution network 250 can have a density of 20%-95% thermal conductors within the portion (e.g., peripheral portion) overlapping the heat-generating circuit (e.g., the PHY 220).

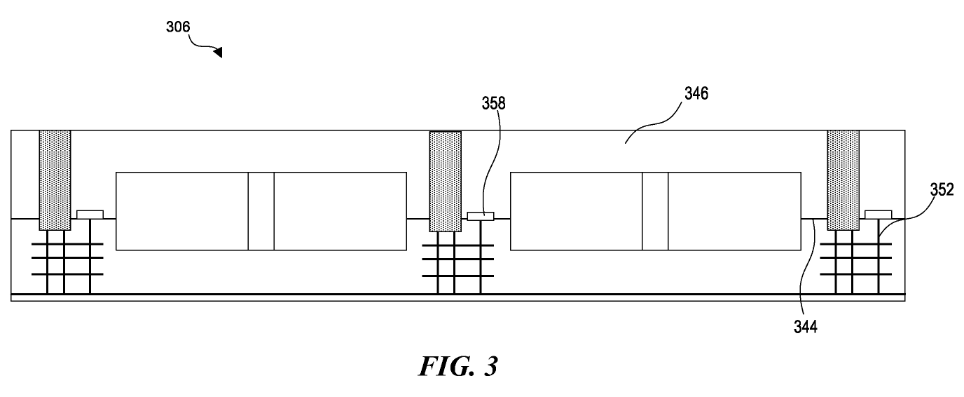

FIG. 3 is a cross-sectional view of a memory die 306 in accordance with an embodiment of the present technology. The memory die 306 can be generally similar to the memory die 206 of FIG. 2A. For example, the memory die 306 can include a thermal distribution network connected to TSVs and located around the functional circuitry, such as the arrays. Additionally, the thermal distribution network of the memory die 306 can include a thermal pad 358 on a front side 344 of the semiconductor substrate 346. The thermal pad 358 can be connected to one or more internal vias 352. Accordingly, the thermal pad 358 can be configured to dissipate the thermal energy received through the internal vias 352 into the semiconductor substrate 346 (e.g., silicon or other thermally conductive and electrically semiconductive material).

### Manufacturing Flow

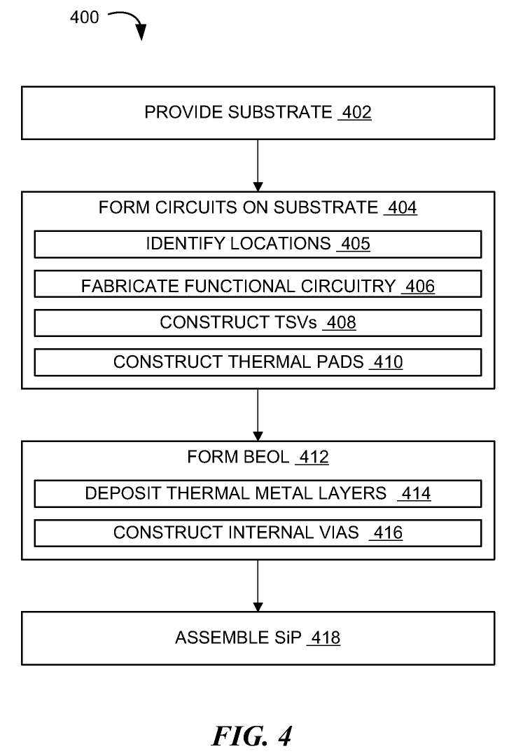

FIG. 4 is a flow diagram illustrating an example method 400 of manufacturing an apparatus (e.g., the SiP 200 of FIG. 2A, the memory device 202 of FIG. 2A, the core dies 206 of FIG. 2A, and/or the memory die 306 of FIG. 3) in accordance with an embodiment of the present technology. The method 400 can include manufacturing the thermal distribution network 250 of FIG. 2A, the thermal pad 358 of FIG. 3, or both and/or a corresponding device or SiP.

At block 402, the method 400 can include providing a semiconductor substrate (e.g., the substrate 246 of FIG. 2B, the substrate 346 of FIG. 3, and/or the like), such as a semiconductor wafer. The semiconductor wafer can be processed to form functional circuitry thereon, such as active components, passive components, electrical connections, power components, and/or the like as shown on block 404.

Forming the circuits on the substrate (e.g., FEOL) can include identifying locations for the circuits as shown on block 405. For example, a manufacturer, a circuit designer, a corresponding system, and/or the like can identify locations of the thermal distribution network 250 of FIG. 2B, the arrays 232 of FIG. 2B, the TSVs 208 of FIG. 2B, the PHY 220 of FIG. 2B or a combination thereof. In some embodiments, the PHY 220 can be identified as being located at or within a threshold distance from a peripheral edge or a corner position of the interface die 204 of FIG. 2B, the thermal distribution network 250 can be identified as being over or overlapping the location of the PHY 220, and the arrays 232 can be identified as being offset away from the PHY 220.

At block 406, the method 400 can include fabricating functional circuitry on the substrate. For example, the array 232 can be formed on the substrate. Fabricating the functional circuitry can include implanting dopants, depositing and shaping conductive material, and/or other similar techniques.

At block 408, the method 400 can include constructing TSVs (e.g., the TSVs 208). For example, the method 400 can include masking the semiconductor substrate 346, etching the semiconductor substrate 346 to form an opening, and then filling the opening with conductive material (e.g., metallic material, such as copper).

At block 410, the method 400 can include constructing thermal pads (e.g., the thermal pad 358) on the semiconductor substrate 346. The thermal pads can be formed on the front side of the semiconductor substrate 346. In some embodiments, the thermal pads can be electrically separated or isolated from the circuits formed on the semiconductor substrate 346. The thermal pads can be constructed by depositing thermally and/or electrically conductive material (e.g., copper, titanium, etc.) at targeted locations on or directly contacting the semiconductor substrate 346.

At block 412, the method 400 can include forming an BEOL structure (e.g., the BEOL 242 of FIG. 2B) on the semiconductor substrate 346. For example, the BEOL 242 can be formed over the front side of the semiconductor substrate 346 by depositing one or more insulative layers (e.g., oxide layers) and/or conductive structures/layers. The conductive structures can include the thermal distribution network 250 at targeted locations, such as between the arrays 232, overlapping the heat generating areas (e.g., the PHY 220 of FIG. 2B), overlapping the TSVs, or a combination thereof.

Forming the BEOL structure can include depositing thermal metal layers (e.g., the lateral thermal connections 254 of FIG. 2B) as shown in block 414 and constructing internal vias (e.g., the internal vias 252 of FIG. 2B) as shown in block 416. For example, after depositing an oxide layer, the method 400 can include forming the lateral thermal connections 254 (e.g., traces) on the oxide layer using patterns, masks, seed layers, or a combination thereof. Also, after depositing an oxide layer, the method 400 can include forming an opening in the oxide layer and then filling the opening to form the internal vias 252. Accordingly, the method 400 can include the density or amount of thermally conductive material over the heat generating areas and/or between the functional circuitry (e.g., the arrays 232) for dissipating and/or routing thermal energy away from the heat generating circuitry.

In some embodiments, forming the BEOL structure can include connecting the internal vias 252 to the thermal pads. For example, the opening in the oxide layer can be formed over and exposing the thermal pad. Thus, when the opening is with conductive material the resulting internal via 252 can directly contact and attach to the exposed portion of the thermal pad.

At block 418, the method 400 can include assembling the SiP (e.g., the SiP 200). For example, the semiconductor dies resulting from the processes described above through blocks 402-416 can correspond to the core dies 206. The core dies 206 can be stacked on top of each other, such as through hybrid bonding and singulation, to form the memory device 202. The resulting memory device 202 can be mounted on the interposer 212 of FIG. 2A along with the processor 210 of FIG. 2A. The resulting structure can be mounted on the package substrate 214 of FIG. 2A.

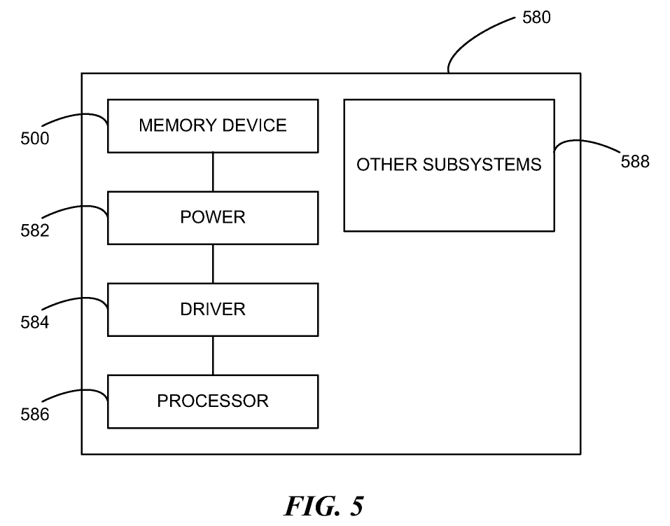

FIG. 5 is a schematic view of a system that includes an apparatus in accordance with embodiments of the present technology. Any one of the foregoing apparatuses (e.g., memory devices) described above with reference to FIGS. 2A-4 can be incorporated into any of a myriad of larger and/or more complex systems, a representative example of which is system 580 shown schematically in FIG. 5. The system 580 can include a memory device 500, a power source 582, a driver 584, a processor 586, and/or other subsystems or components 588. The memory device 500 can include features generally similar to those of the apparatus described above with reference to FIGS. 2A-4, and can therefore include various features for performing a direct read request from a host device. The resulting system 580 can perform any of a wide variety of functions, such as memory storage, data processing, and/or other suitable functions. Accordingly, representative systems 580 can include, without limitation, hand-held devices (e.g., mobile phones, tablets, digital readers, and digital audio players), computers, vehicles, appliances and other products. Components of the system 580 may be housed in a single unit or distributed over multiple, interconnected units (e.g., through a communications network). The components of the system 580 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term "processing" as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system- generated data, such as calculated or generated data, and program data. Further, the term "dynamic" as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 2A-5.

We claim:

1. A heterogenous integrated chiplet comprising:
an interface die having a physical layer interface circuit (PHY) configured to communicate signals with an external circuit; and
a core die mounted over the interface die, the core die including:
a semiconductor substrate having a set of arrays and a Through Silicon Via (TSV) extending through a thickness of the semiconductor substrate, wherein the TSV overlaps the PHY, and
a back end of the line (BEOL) structure formed on a side of the semiconductor substrate facing the interface die,
the BEOL including a thermal distribution network overlapping the PHY and thermally coupled to the TSV, wherein the thermal distribution network includes metallic material configured to route thermal energy away from the PHY and across the BEOL by increasing the density of thermally conductive material in the BEOL.

2. The heterogenous integrated chiplet of claim 1, wherein the thermal distribution network includes traces extending laterally and contacting internal vias that extend vertically, wherein the internal vias extend at least partially through a thickness of the BEOL and contacts the TSV.

3. The heterogenous integrated chiplet of claim 2, wherein the traces, the internal vias, or both are electrically isolated from the set of arrays and the PHY.

4. The heterogenous integrated chiplet of claim 2, wherein the traces and the internal vias are connected to electrical ground.

5. The heterogenous integrated chiplet of claim 2, wherein:
the internal vias are a first set of internal vias;
further comprising:
a thermal pad on the side of the semiconductor substrate facing the interface die, wherein the thermal pad contacts the semiconductor substrate and is electrically isolated from the set of array, wherein the thermal pad directly contacts the semiconductor substrate; and
a second internal via extending vertically and contacting the laterally extending traces, wherein the second internal via extends at least partially through the thickness of the BEOL and contacts the thermal pad for routing the thermal energy from the PHY into the semiconductor substrate through the thermal pad.

6. The heterogenous integrated chiplet of claim 2, wherein:
the traces comprise a first group of traces;
the internal vias comprise a first group of internal vias;
the TSV is a first TSV;
the set of arrays includes a first circuit grouping and a second circuit grouping;
the thermal distribution network including a second group of traces and a second group of internal vias in the BEOL structure and located between the first and second circuit groupings, wherein the second group of traces is thermally coupled to the first group of traces; and
the heterogenous integrated chiplet further comprising:
a second TSV extending vertically through the thickness of the semiconductor substrate and between the first and second circuit groupings, the second TSV directly contacting the second group of internal vias for removing the thermal energy away from the PHY.

7. The heterogenous integrated chiplet of claim 1, wherein:
the core die is a first core die;
the semiconductor substrate is a first semiconductor substrate;
the TSV is a first TSV;
the BEOL structure is a first BEOL structure;
the thermal distribution network is a first thermal distribution network;
further comprising:
a second core die stacked over the first core die, the second core die including:
a second semiconductor substrate having a second TSV extending through a thickness of the second semiconductor substrate, wherein the second TSV overlaps the first TSV, and
a second BEOL structure formed on a side of the second semiconductor substrate facing the first core die,
the second BEOL structure including a second thermal distribution network overlapping the first thermal distribution network and thermally coupled to the second TSV,
wherein the second thermal distribution network includes metallic material configured to remove thermal energy away from the first TSV and across the second BEOL,
wherein the first thermal distribution network, the first TSV, the second thermal distribution network, and the second TSV are vertically aligned and positioned over the PHY.

8. The heterogenous integrated chiplet of claim 7, wherein:
the interface die includes a first peripheral edge opposite a second peripheral edge, and the PHY is closer to the first peripheral edge than the second peripheral edge; and
the set of arrays on the first core die is offset from a mid-point between the first and second peripheral edges and closer to the second peripheral edge than the first peripheral edge.

9. The heterogenous integrated chiplet of claim 7, wherein at least the first and second core dies are connected to each other through wafer-level bonding.

10. The heterogenous integrated chiplet of claim 7, wherein the heterogenous integrated chiplet is a High-Bandwidth Memory (HBM) device.

11. A semiconductor device configured to be placed over an external device having a heat generating portion therein, the semiconductor device comprising:
a semiconductor substrate;
functional circuitry formed on the semiconductor substrate;
a Through Silicon Via (TSV) extending through a thickness of the semiconductor substrate, wherein the TSV is located at a portion of the semiconductor substrate configured to overlap the heat generating portion of the external device; and
a back end of the line (BEOL) structure formed on the semiconductor substrate and over the functional circuitry,
the BEOL including a thermal distribution network overlapping and thermally coupled to the TSV, wherein the thermal distribution network includes thermally conductive material configured to remove thermal energy away from the heat generating portion and across the BEOL to the TSV.

12. The semiconductor device of claim 11, wherein:
the BEOL structure includes electrically insulative layers and signal traces disposed between the electrically insulative layers; and
the thermal distribution network includes (1) traces disposed between the electrically insulative layers and extending laterally and (2) internal vias that contact the TSV and the traces, the internal vias extending vertically across at least one of the electrically insulative layers.

13. The semiconductor device of claim 12, wherein the traces, the internal vias, and the TSV are electrically isolated from the functional circuitry.

14. The semiconductor device of claim 12, wherein the traces, the internal vias, and the TSV are connected to an electrical ground used for the functional circuitry.

15. The semiconductor device of claim 12, wherein:
the traces comprise a first group of traces;
the internal vias comprise a first group of internal vias;
the TSV is a first TSV;
the functional circuitry includes a first circuit grouping spaced apart from a second circuit grouping along a lateral direction;
the thermal distribution network including a second group of traces and a second group of internal vias in the BEOL structure and located between the first and second circuit groupings along the lateral direction, wherein the second group of traces is thermally coupled to the first group of traces; and
the semiconductor device further comprising:
a second TSV extending vertically through the thickness of the semiconductor substrate and between the first and second circuit groupings, the second TSV directly contacting the second group of internal vias.

16. The semiconductor device of claim 11, wherein the functional circuitry includes memory cells.

17. A method of manufacturing a semiconductor device, the method comprising:
providing a semiconductor substrate having a frontside and a backside;
forming functional circuitry on the frontside of the semiconductor substrate;
construction a TSV that extends through a thickness of the semiconductor substrate, wherein the TSV is formed at a location that is projected to overlap a heat generating portion of an external device when the semiconductor device is attached over the external device;
forming a front end of the line (FEOL) structure over the frontside, wherein the BEOL structure includes:
electrically insulative layers;
signal traces disposed between the electrically insulative layers and electrically coupled to the functional circuitry;
a thermal distribution network overlapping and thermally coupled to the TSV wherein the thermal distribution network includes thermally conductive material configured to remove thermal energy away from the heat generating portion and across the BEOL to the TSV.

18. The method of claim 17, the wherein:
the functional circuitry includes memory cells;
the external device is an interface structure configured to facilitate communications between the memory cells and a host;
the heat generating portion is a physical layer interface circuit (PHY) configured to communicate signals corresponding to the facilitated communications; and
the method further comprising:
attaching the semiconductor substrate and the corresponding BEOL over the interface structure with the TSV and the thermal distribution network overlapping the PHY.

19. The method of claim 18, wherein:
the semiconductor substrate is a first semiconductor wafer having the functional circuitry and the BEOL structure thereon;
the interface structure is a second semiconductor wafer;
attaching the semiconductor substrate over the interface structure includes bonding the first semiconductor wafer and the second semiconductor wafer;
the method further comprising:
forming a heterogenous integrated chiplet based on singulating a portion of the bonded first and second semiconductor wafers, wherein the TSV, the PHY, and the thermal distribution network are aligned along a vertical line located between the functional circuitry and a peripheral edge of the heterogenous integrated chiplet.

20. The method of claim 18, further comprising:
forming a thermal pad directly contacting the frontside and electrically isolated from the functional circuitry, wherein the thermal pad is thermally coupled to the thermal distribution network for routing the thermal energy into the semiconductor substrate through the thermal pad.
